(19) United States
(12) Patent Application Publication
(10) Pub. No.: US 2023/0044068 A1
(43) Pub. Date: Feb. 9, 2023

(54) Plasma Resistant YxHfyOz Homogeneous Films and Methods of Film Production

(71) Applicant: Greene, Tweed Technologies, Inc., Wilmington, DE (US)

(72) Inventors: Alexadru C. Pavel, Austin, TX (US); Vasil Vorsa, Coopersburg, PA (US)

(73) Assignee: Greene, Tweed Technologies, Inc., Wilmington, DE (US)

(21) Appl. No.: 17/875,570

(22) Filed: Jul. 28, 2022

Related U.S. Application Data
(60) Provisional application No. 63/226,272, filed on Jul. 28, 2021.

(51) Int. Cl. C23C 16/455; C23C 16/40; C23C 16/44

(52) U.S. Cl. CPC C23C 16/45553; C23C 16/405; C23C 16/4408; C23C 16/45542

(57) ABSTRACT

Disclosed herein is a method for producing a film of mixed yttrium and hafnium oxides, nitrides or fluorides on a substrate by an atomic layer deposition process. The process includes providing a reaction chamber containing a substrate, pulsing into the chamber an yttrium source reactant; purging the chamber with a purging material; pulsing into the chamber a co-reactant precursor; purging the chamber with a purging material (first subcycle); pulsing into the chamber a hafnium source reactant; purging the chamber with a purging material; pulsing into the chamber a co-reactant precursor; urging the chamber with a purging material (second subcycle). Each subcycle may be repeated multiple times in a super cycle.

### CROSS-REFERENCE TO RELATED APPLICATION

This application claims the benefit under 35 U.S.C. § 119(e) of U.S. Provisional Patent Application Ser. No. 63/226,272 filed Jul. 28, 2021 and entitled “Plasma Resistant YₓHf_{y}O_{z} Homogeneous Films and Methods of Film Production”, the entire disclosure of which is incorporated herein by reference.

### BACKGROUND OF THE INVENTION

To prevent contamination of semiconductor wafers, semiconductor manufacturing equipment and flat panel display manufacturing equipment are made of high purity materials with low plasma erosion properties. During manufacturing, these materials are exposed to highly corrosive gases, particularly halogen-based corrosive gases such as fluorine and chorine-based gases. Materials in the processing equipment are required to have a high resistance to erosion. To address this need, ceramic films or coatings such as alumina and yttria have been applied. The most frequently used method in semiconductor technology to apply these films is thermal spray and all its variations. However, even these materials erode over leading to lower yield and costly down time.

Thus, there is a need for films with improved resistance to erosion. To meet these objectives, technologists have turned to development of various atomic layer deposition (ALD) processes to aid in the deposition of plasma-resistant films. Advantages of ALD-formed films include conformal, dense, and pinhole-free film or coating that can coat complex 3D shapes and high-aspect ratio holes.

Yttrium oxide (Y₂O₃) or yttria has been used for many years as the industry standard for formation of plasma-resistant films in semiconductor dry processing chambers. However, as node sizes continue to shrink, the industry is looking for new materials that have increased plasma-resistant properties. Thus, there exists a need in the art for a process of making and the resultant film having an even lower etch rate (i.e., greater resistance to erosion) than the conventional ALD deposited-yttrium oxide films whether such films are exposed to direct RIE (reactive-ion etching) plasma conditions, ICP (inductively-coupled) plasma conditions, or a combination of these.

### BRIEF SUMMARY OF THE INVENTION

Disclosed herein is a method for producing a film of mixed yttrium and hafnium oxides, nitrides or fluorides on a substrate by an atomic layer deposition process. The process includes providing a reaction chamber containing a substrate, pulsing into the chamber an yttrium source reactant; purging the chamber with a purging material; pulsing into the chamber a co-reactant precursor; purging the chamber with a purging material (first subcycle); pulsing into the chamber a hafnium source reactant; purging the chamber with a purging material; pulsing into the chamber a co-reactant precursor; urging the chamber with a purging material (second subcycle). Each subcycle may be repeated multiple times in a super cycle.

The process provides for the formation of a homogenous film of substantially mixed yttrium and hafnium oxides, nitrides, or fluorides. Films prepared by this process are also included.

Also included are methods of reducing fluorine incorporation of a yttrium film during fluorination etch processes and methods of improving the smoothness of thick yttrium films.

### BRIEF DESCRIPTION OF THE SEVERAL VIEWS OF THE DRAWINGS

The foregoing summary, as well as the following detailed description of preferred embodiments of the invention, will be better understood when read in conjunction with the appended drawings. For the purpose of illustrating the invention, there is shown in the drawings embodiments which are presently preferred. It should be understood, however, that the invention is not limited to the precise arrangements and instrumentalities shown. In the drawings:

FIG. 1 is a flowchart illustrating an overview of the process steps of an embodiment of the invention;

FIG. 2 is a table listing exemplary precursors that may be used in various combinations to deposit the films of the invention.

FIG. 3 is a chart showing a comparison of etch rates for the film prepared in accord with the invention, a convention Y₂O₃ film and a conventional HfO₂ film;

FIG. 4 is a TEM cross section of a film embodiment of the invention showing a homogenous Y_{1.1}Hf_{1.0}O_{4.2} composition of a mixed film embodiment of the invention;

FIG. 5 is an EDS cross sectional line scan of the film of FIG. 4, also demonstrating a homogenous film;

FIG. 6 is TEM cross section of another film embodiment of the invention showing a homogenous Y_{3.4}Hf_{1.0}O_{7.4} composition of a mixed film embodiment of the invention;

FIG. 7 is a chart showing a comparison of etch rates for the two films prepared in accord with the invention;

FIG. 8 is two SEM cross-section images comparing surface smoothnesses of a ˜500 nm thick conventional Y₂O₃ film (top SEM) and ˜500 nm Y_{1.1}Hf_{1.0}O_{4.2} film that is an embodiment of the invention (bottom SEM); and

FIG. 9 shows the fluorine incorporation as evaluated by X-ray photoelectron spectroscopy post-etch of the conventional Y₂O₃ and Y_{1.1}Hf_{1.0}O_{4.2} films depicted in FIG. 3.

### DETAILED DESCRIPTION OF THE INVENTION

The semiconductor industry is aggressively seeking films that provide and even greater resistance to, for example, plasma erosion, than the conventional ALD—deposited yttria film. The invention as described herein includes atomic layer deposition-based (ALD-based) methods of depositing films of mixed yttrium and hafnium oxides, nitrides, and/or fluorides that exhibit an improved resistance to plasma erosion or etch. In addition, it has been found that the films of the invention are advantageous as compared to convention films because they exhibit a higher resistance to fluorine incorporation from fluorine etch processes and they remain smooth—surfaced at high thicknesses—a desirable property because smoother films are less susceptible to particulation.

As used herein, a “thick” film has a thickness of about 200 to about 1000 nm, about 300 to about 700 nm and/or about 500 to about 600 nm.

The methods and films described herein were initially contemplated for use in the semiconductor industry. However, the methods, films, and film-bearing substrates of the invention in their various embodiments are useful for deposition on substrates that form components useful in a variety of industries, especially those where components may be exposed to high temperatures, and/or corrosive chemicals. For example, the films of the invention may be used on components that are found in equipment/machines/devices used in aerospace, pharmaceutical production, food processing, oil field applications, military and/or maritime applications, industrial manufacturing, and scientific and/or diagnostic instrumentation.

The practice of the method includes a substrate to which the film is applied. The substrate may be any material useful for the desired end applications. In some embodiments, one may prefer that the substrate is a non-ferrous metal, a non-ferrous metal alloy, a ferrous metal or a ferrous metal alloy. Suitable materials may include substrates of titanium, aluminum, nickel, nickel alloys, ceramics, aluminum alloys, steels, stainless steel, carbon steel, alloy steel, copper, copper alloys, lead, lead alloys, ceramics, sapphire, quartz, a glass, a polymer, such as a high-performance polymer, and a fiberglass. The substrate may also combine materials, that is, a portion may be, for example, made of aluminum and an adjacent portion made of copper. A silicon substrate may be preferred in some embodiments.

The film-bearing substrate may make up or be part of a variety of components, such as, for example, components that are planar in nature or have a 3D geometry. For example, the component may be a chamber component, like a shower head, a chamber wall, a nozzle a plasma generation unit, a diffuser, a gas line interior, a chamber orifice, and the like.

As noted, the invention may be used in any sector of industry. However, a development focus of the invention included substrates in the semiconductor manufacture arena. In semiconductor manufacturing, the processes used expose semiconductor process chamber components to high temperatures, high energy plasma, a mixture of corrosive gases, and/or high-level stressors. Depositing protective films, such as those of the invention described herein, on semiconductor process chamber components is an effective way to reduce defects and extend their use lifetime.

As used herein, the term “chamber component” refers to a component used in a semiconductor manufacturing process chamber, such as, for example, a plasma etcher or plasma etch reactor, a plasma cleaner, a remote plasma generator, and a plasma deposition system. Without limitation, examples of these components include substrate support assemblies, wafer boats, electrostatic chucks, rings, chamber walls, radio frequency (RF) windows, chamber bases, gas distribution plates, gas lines, gas nozzles, portals, showerheads, lids, liners, shields, escutcheons, plasma screens, flow equalizers, cooling bases, fasteners, ports, optical windows, etc.

Once the substrate is selected it is placed in the reaction chamber of an ALD tool. Any ALD tool may be used; they are commonly available, such as, for example, those from Picosun (P-series and R-series ALD systems); Beneq Oy (TFS-series or P-series) Oxford Instruments (FlexAl and OpalAl ALD systems); and/or Veeco Instruments (Savannah, Fiji, and Phoenix ALD systems).

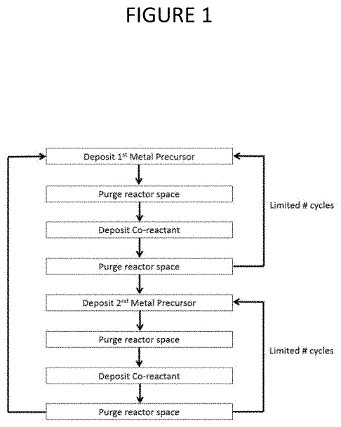

The method described herein is illustrated schematically in the flowchart of FIG. 1. With reference to FIG. 1 and using the known protocols associated with selected ALD tool, the method in general description includes two sub cycles.

In the first sub cycle, the substrate is present in a chamber into which a vapor phase pulse of an yttrium source reactant is provided, followed by a purge step. This is followed by a vapor phase pulse into the chamber of a co-reactant material. The chamber is purged again.

The steps of the second sub cycle are the same, except that a hafnium sources reactant is used in place of the yttrium source reactant and the same or a different co-reactant material may be selected.

Each sub cycle is independently carried out about 1 to about 50 or about 4 to about 32 times. To ensure “mixing” of the yttrium oxide/nitride/fluoride with the hafnium oxide/nitride/fluoride in the final film (rather than layering), it may be preferred that each pulse of the sources material(s) performed in the sub cycles is relatively short, for example, about 0.01 to about 10 seconds or about 0.01 to about 120 seconds. In some instances, if the process is carried out under a lower pressure, the pulses may be longer. Note that the duration of the pulse can be varied for each performance of sub cycle—it need not be the same in each instance.

After completion of both cub cycles, the entire method may be performed again. For each iteration of the method, the pulse times may be varied.

The purging step in each of the sub cycles is about 0.01 to about 120 seconds in some embodiments. In various embodiments, the purge step(s) can be accomplished using any suitable purging material. Nitrogen may be preferred in some embodiments. Argon, or any other inert gas(es) in place of or mixed with nitrogen might also be used.

It is noted that the dose and purge times given above in ranges are merely illustrative. It is well within the skillset of a person of ordinary skill in the art to determine dose time and purges times for an ALD process. For example, in various embodiments the ratio of Y to Hf may be varied to meet the requirements of a specific end application, use of a specific substrate and the like, and/or adjusting the Y to Hf ratio can result in differing rates of plasma resistance depending on other variables present in the process.

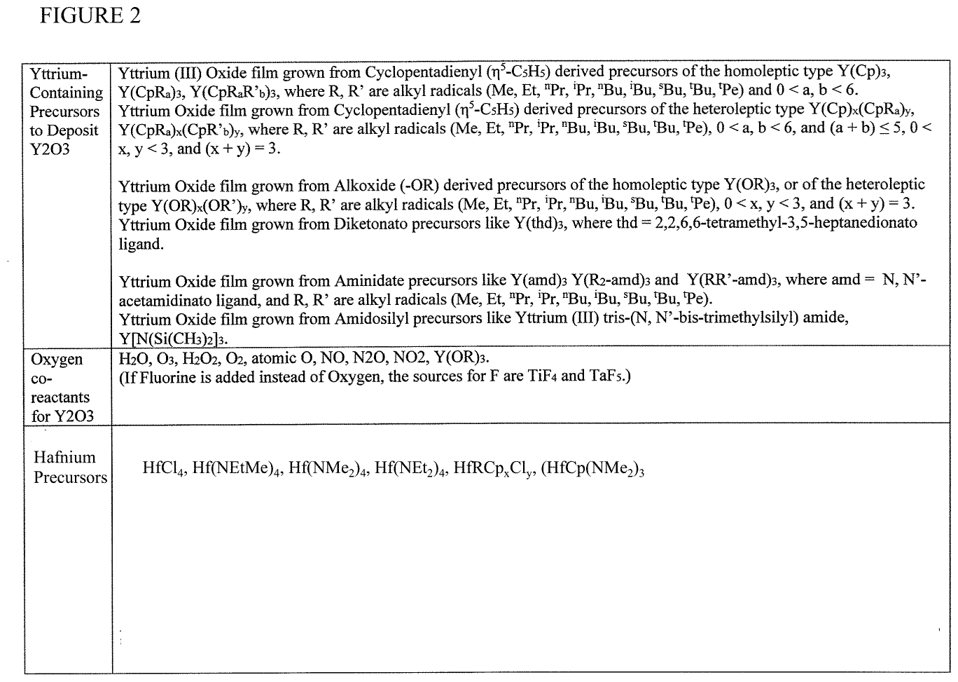

Yttrium source reactants that may be used in the inventive method include any known or to be developed in the art, for example, those shown in FIG. 2 for yttrium. In some embodiments, one may prefer to use an yttrium source reactant that is a is a cyclopentadienyl compound or a derivative of a cyclopentadienyl compound.

Hafnium source reactants that may be used in the inventive method include any known or to be developed in the art, for example, any amino based precursor; tetrakis(dimethylamido)hafnium, tetrakis(ethylmethylamino)hafnium, or tetrakis(diethylamido)hafnium, Bis(trimethylsilyl)amidohafnium(IV) chloride and similar or alkoxide-based precursors such as tetraethoxyl hafnium or hafnium tetraichloride. See, e.g., those of FIG. 2.

Co-reactant precursors that may be used in the inventive method include any known or to be developed in the art, for example, oxidizer precursors (to grow oxides), fluoride precursors (to grow fluorides), and/or nitride precursors (to grow nitrides).

Specific examples include, without limitation, water, O₂, O₂ plasma, O₃, H₂O₂, N₂O, NO₂, NO and mixtures of the same (oxidizer precursors), hydrogen fluoride (“HF”), HF-pyridine, (fluoride precursors), NH₄F, TiF₄, TaF₅, tetrakis(dimethylamino)titanium (IV) (TDMAT), NH₃, H₂N—NH₂ (nitride precursor). Other examples, without limitation, are shown the table of FIG. 2. In an embodiment, it may be preferred but not necessary that the co-reactant precursor is the same for each repetition of a given sub cycle.

The films formed by the process of the invention may be of any thickness desired; desired thicknesses will vary depending on the end application in which the coating or coated substrate (article) is to be used. As an example, the film may have a thickness of about 10 to about 10,000 nanometers of about 30 to about 100 nanometers and/or of about 40 to about 60 nanometers.

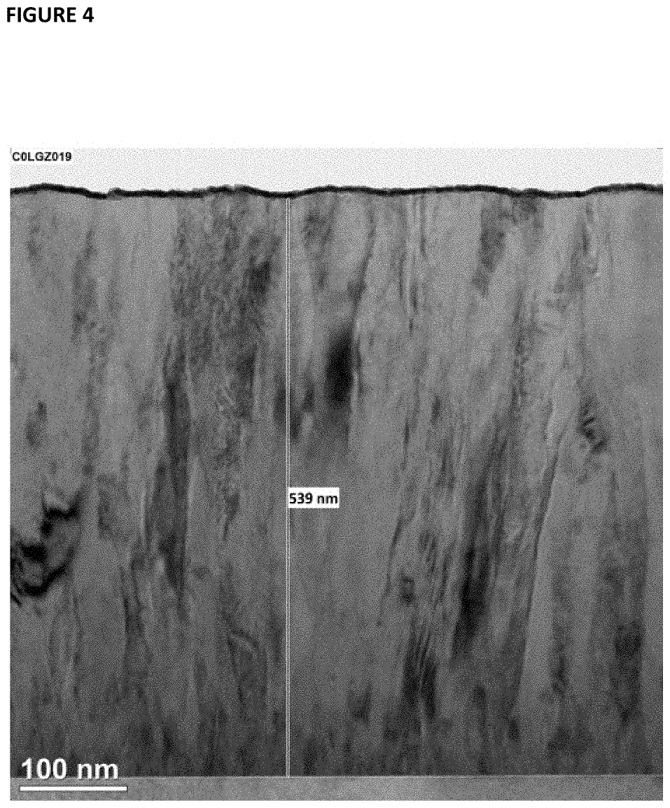

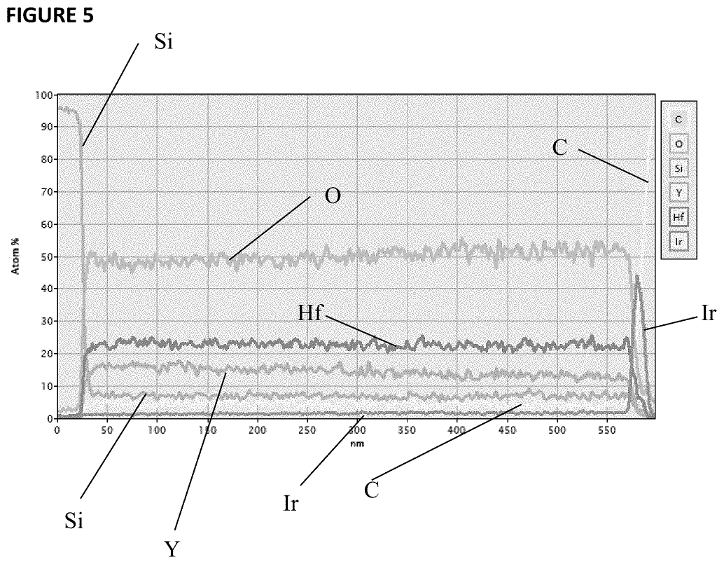

The films of the invention are substantially homogeneous. As used herein “homogenous” and its grammatical counterparts refer to the fact that the film so-described is free of well-defined or differentiated layers when viewed via TEM in a 10, 20, or 100 nm section and/or no area of the film is a single component above the molecular level. See, for example, the micrograph of FIG. 4 and the EDS. FIG. 4 is a TEM cross section of a film embodiment of the invention exhibiting a totally homogenous YₓHf_{y}O_{z} mixed film with no indication of “stacks” or “layers”. FIG. 5 shows the EDS cross sectional line scan of the same film, also demonstrating a homogenous film.

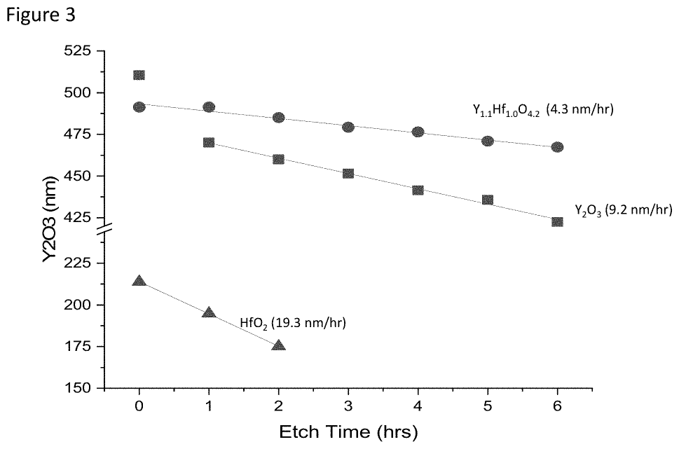

The film prepared by the methods of the invention exhibits an etch rate that is about 1 time, 1.5 times, 2 times lesser than an etch rate of a conventional yttrium oxide film of the same thickness on the same substrate, where etch rate is expressed as the ratio of film etched away (removal) over time (ratio of change of thickness to time interval). Illustration of this property in an embodiment of the invention is exemplified in FIG. 3, which is a chart showing a comparison of etch rates for the film prepared in accord with the invention, a conventional Y₂O₃ film and a conventional HfO₂ film. To obtain the data shown in FIG. 3, etch rates were evaluated in a Trion Phantom II CCP RIE plasma etcher on with each of the films begin deposit via ALD on an existing silicon film. As can be seen from the Figure the YₓHf_{y}O_{z} film of the invention exhibited a 4.5× lower etch rate than the conventional HfO₂ film, and a 2.1×lower etch rate than the conventional Y₂O₃ film. Such results are also set forth in Table 1, below.

TABLE 1

| Film | Etch Rate (nm/hr) |
|---|---|
| Y_{1.1}Hf_{1.0}O_{4.2} | 4.3 ± 0.3 |
| Y₂O₃ | 9.2 ± 0.4 |
| HfO₂ | 19.4 ± 0.2 |

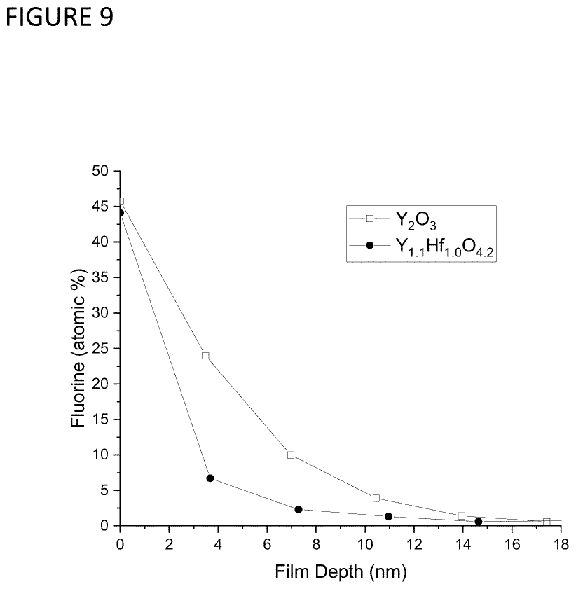

The film prepared by the methods of the invention exhibits a higher resistance to fluorine incorporation from fluorine etch processes as compared the fluorine incorporation exhibited by similar conventional Y₂O₃ films. Fluorination of a film during etch processing or process chamber cleaning is a disadvantage a it produces film volume expansion which can lead to particle generation. With the decreased fluorine incorporation experienced by the films of the invention, the risk of particle generation is reduced. An embodiment of the invention, a film of Y_{1.1}Hf_{1.0}O_{4.2} was found to have less fluorine incorporation than conventional Y₂O₃ film. Data in support of this conclusion is provide in FIG. 9. FIG. 9 shows the fluorine incorporation as evaluated by X-ray photoelectron spectroscopy post-etch of the conventional Y₂O₃ and Y_{1.1}Hf_{1.0}O_{4.2} films depicted in FIG. 3.

In an embodiment, the films of the invention may alternatively be formed using the process described in U.S. patent application Ser. No. 17/356,444, filed Jun. 23, 2021, the entire contents of which are incorporated herein by reference. Illustratively, the process described therein includes carrying out an ALD deposition cycle that includes at least the steps of: providing an ALD reactant chamber with a substrate; pulsing into the chamber the yttrium metal coating precursor; pulsing into the chamber the hafnium metal precursor substantially immediately after the completion of the yttrium pulse; purging the chamber; pulsing into the chamber a an oxygen-containing co-reactant precursor; and purging the chamber. At completion of a cycle, a monolayer is deposited. The monolayer is or is included in a mixed coating of substantial homogeneity.

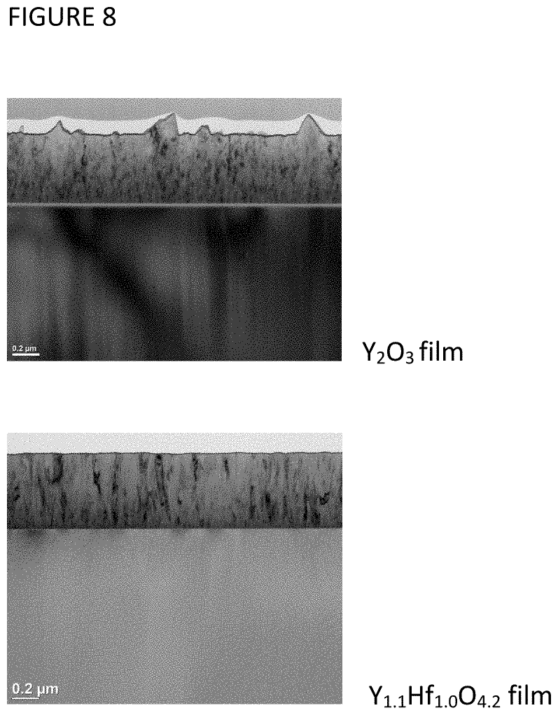

Additionally, the films of the invention remain smooth surfaced at thickness when compared to conventional Y₂O₃ films of similar thicknesses. Smoother films are less susceptible to particulation. Nominal 500 nm Y_{1.1}Hf_{1.0}O_{4.2} (prepared by the process of the invention) and conventional Y₂O₃ films on silicon were evaluated for surface roughness with Atomic Force Microscopy (AFM). 500 nm Y_{1.1}Hf_{1.0}O_{4.2} was found to be ˜15× smoother than 500 nm Y₂O₃ (Figure XX). SEM analysis of the two films showing this phenomenon is in FIG. 8.

In an embodiment, the substrate may be pretreated by cleaning or heating before beginning the process. Additionally, one may wish to deposit a preliminary or primer layer on the substrate before initiating the above-described process. The primer layer may be a metal oxide layer, for example, aluminum oxide. It may be formed by any process including, for example, ALD, anodization, thermal spray, sputtering, vapor deposition and evaporation techniques.

Also, one may subject the film to an annealing step as is known or developed in the art. In some embodiments, the deposited mixed homogeneous film may be annealed or subject to other post-deposition processes.

### Example 1

Thick YxHfyOz plasma etch-resistant films with an yttrium to hafnium ratio of approximately 1 to 1 were prepared by deposition on the surface of a silicon substrate using a standard cross-flow type ALD reactor. The process for each was as follows: A 100 mm silicon wafer substrate was placed in a wafer holder placed inside the ALD reactor. The reactor was then pumped down with a vacuum pump while purging with nitrogen to a pressure of between 0.2 and 2 torr. The temperature of the reaction chamber was set to 350° C. The flow rates through all the precursor delivery lines were all set at 150 sccm.

YxHfyOz was deposited using a cyclopentadienyl-based yttrium compound as the yttrium source reactant, an amino-based hafnium compound as the hafnium source reactant, and water as the co-reactant. The yttrium and hafnium precursor vessel temperatures were set to deliver approximately 0.30 torr of vapor pressure, while the water vessel temperature was set to deliver approximately 20 torr.

The process begins with a short (8×) half-cycle of water pulsing (0.2 seconds)/purging (24.0 seconds) to hydroxylate the Si atoms of the wafer surface.

The YₓHf_{y}O_{z} film was formed by employing 2 sub-cycles of an Y₂O₃ process followed by 2 sub-cycles of an HfO₂ process. Each Y₂O₃ and HfO₂ sub-cycle employed the following sequence: the metal precursors were pulsed for 2 seconds each followed by a 12 second nitrogen purge, followed by a 0.2 second water pulse, followed by an 18 second nitrogen purge. The water dosing scheme was then repeated, for a multiplicity of 2.

The two sub-cycles were then repeated 1,710 times in a super-cycle to build up a thick layer of YₓHf_{y}O_{z}. It should be noted that even though the Y₂O₃ and HfO₂ subcycles were separately carried out, the resulting film(s) did not exhibit distinct layers or regions of either Y₂O₃ or HfO₂. See, e.g., FIGS. 4 and 5.

The process was ended with a short (4×) half-cycle of water pulsing (0.2 seconds)/purging (24.0 seconds) for the hydroxylation of the ternary oxide film surface. The resulting film(s) was 100% polycrystalline structure with a formula of Y_{1.1}Hf_{1.0}O_{4.2}.

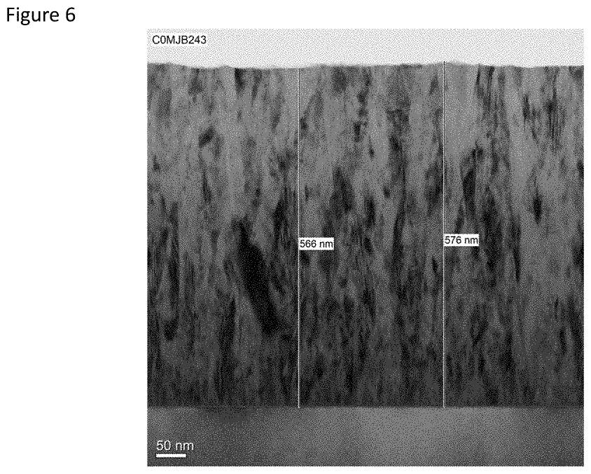

Four films were prepared in this manner. The average thickness of the films prepared was 525 nm. For illustrative purposes, a TEM of one of the films so prepared is shown in cross section in FIG. 6.

### Example 2

A thick YₓHf_{y}O_{z} plasma etch-resistant film (FIG. 6) with an yttrium to hafnium ratio of approximately 3.4 to 1 was deposited on the surface of a silicon substrate using the same conditions as outlined in Example 1, but with differing sub cycles as described below.

Specifically, the YₓHf_{y}O_{z} film was formed by employing 3 sub-cycles of an Y₂O₃ process followed by 1 sub-cycle of an HfO₂ process. Each Y₂O₃ and HfO₂ sub-cycle employed the following sequence: the metal precursors were pulsed for 2 seconds each followed by a 12 second nitrogen purge, followed by a 0.2 second water pulse, followed by an 18 second nitrogen purge. The water dosing scheme was then repeated, for a multiplicity of 2.

The process was ended with a short (4×) half-cycle of water pulsing (0.2 seconds)/purging (24.0 seconds) for the hydroxylation of the ternary oxide film surface. The resulted film was a mostly polycrystalline with a formula of Y_{3.4}Hf_{1.0}O_{7.4}.

Four films were prepared in this manner. The average thickness of the films prepared was 570 nm.

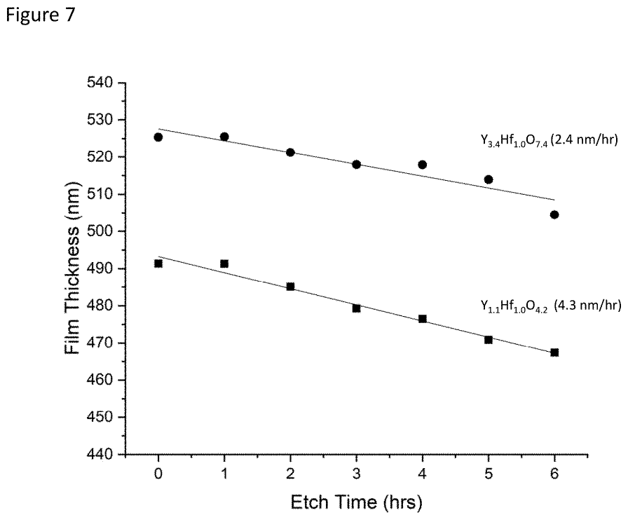

The etch rate of this film with higher Y to Hf ratio was measured using the same etch conditions described above for the Y_{1.1}Hf_{1.0}O_{4.2} film. The Y_{3.4}Hf_{1.0}O_{7.4} film was found to have an approximately 30% lower etch rate (see, e.g., FIG. 7) as compared to the nearly 1 to 1 Y to Hf film. These data are also set forth in tabular form below (Table II).

TABLE II

| Film | Etch Rate (nm/hr) |
|---|---|
| Y_{1.1}Hf_{1.0}O_{4.2} | 4.3 ± 0.3 |
| Y_{3.4}Hf_{1.0}O_{7.4} | 2.4 ± 0.5 |

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A method for producing a film of mixed yttrium and hafnium oxides, nitrides or fluorides on a substrate by an atomic layer deposition process comprising:
a. Providing a reaction chamber containing a substrate;
b. Pulsing into the chamber an yttrium source reactant;
c. Purging the chamber with a purging material;
d. Pulsing into the chamber a co-reactant precursor;
e. Purging the chamber with a purging material;
f. Pulsing into the chamber a hafnium source reactant;
g, Purging the chamber with a purging material;
h. Pulsing into the chamber a co-reactant precursor;
i, Purging the chamber with a purging material;
to form a film of substantially mixed yttrium and hafnium oxides, nitrides or fluorides.

2. The method of claim 1 wherein the film of substantially mixed yttrium and hafnium oxides, nitrides or fluorides exhibits a lesser etch rate as compared to films of Y₂O₃.

3. The method of claim 1, wherein steps b to e are repeated 1-32 times before proceeding to step f.

4. The method of claim 1, wherein steps f to i are repeated 1-32 times.

5. The method of claim 1, wherein the yttrium source reactant is a cyclopentadienyl compound or a derivative of a cyclopentadienyl compound.

6. The method of claim 1, wherein the hafnium source reactant is an amino based compound.

7. The method of claim 1 wherein the co-reactant precursor is an oxidizer precursor (OxPre).

8. The method of claim 7 wherein the OxPre is selected from water, hydrogen peroxide, ozone, O₂, O₂— plasma and/or mixtures thereof.

9. The method of claim 1 wherein the co-reactant precursor is independently selected from a fluoride precursor and a nitride precursor.

10. The method of claim 1, wherein the substrate comprises a material selected from a non-ferrous metal, a non-ferrous metal alloy, a ferrous metal, and a ferrous metal alloy.

11. The method of claim 1, wherein the substrate comprises a material selected from titanium, aluminum, nickel, zinc, aluminum alloys, steels, stainless steel, carbon steel, alloy steel, copper, copper alloys, nickel alloys, lead, and lead alloys.

12. The method of claim 1 wherein the substrate is a chamber component.

13. The method of claim 1 wherein the substrate is selected from a shower head, a chamber wall, a nozzle a plasma generation unit, a diffuser, a gas line interior, and a chamber orifice.

14. The method of claim 1 wherein the substrate is selected from a planar member and a 3D shape, a 3D shape with high aspect ratio features and a 3D shape with low aspect ratio features.

15. The method of claim 1, wherein the purging material is nitrogen.

16. The method of claim 1 wherein the film has a thickness of about 1 to about 250 nanometers.

17. The method of claim 1 wherein the film has a thickness of about 10 to about 5,000 nanometers.

18. The method of claim 1 wherein the film has a thickness of about 40 to about 60 nanometers.

19. The method of claim 1 wherein the film comprises a structure that is polycrystalline.

20. A plasma resistant film prepared by the method of claim 1.

21. The film of claim 20 having a thickness of about 1 to about 250 nanometers.

22. The film of claim 20 having a thickness of about 10 to about 5,000 nanometers.

23. The film of claim 20 having a thickness of about 40 to about 60 nanometers.

24. A component comprising the film of claim 20.

25. The component of claim 24 selected from the group consisting of semiconductor manufacturing equipment, flat panel display manufacturing equipment, a shower head, a chamber wall, a nozzle a plasma generation unit, a diffuser, a gas line interior, and a chamber orifice, chamber liner, and chamber lid.

26. A method for producing a film of mixed yttrium and hafnium oxides, on a substrate by an atomic layer deposition process comprising:
a. Providing an ALD reactant chamber with a substrate;
b. Pulsing into the chamber an yttrium-containing precursor;
c. Pulsing into the chamber a hafnium-containing precursor, substantially immediately after the completion of the yttrium containing precursor pulse;
d. Purging the chamber;
e. Pulsing into the chamber an oxygen-containing co-reactant; and
f. Purging the chamber,
to deposit a monolayer, wherein the coating thereby formed is a mixed coating of substantial homogeneity.
